(19) United States
(12) Patent Application Publication
(10) Pub. No.: US 2006/0273419 A1
(43) Pub. Date: Dec. 7, 2006

(54) Magnetic field sensing device

(76) Inventors: Steven L. Lindblom, Hastings, MN (US); Michael B. Hintz, Mahtomedi, MN (US); Richard E. Jewett, Minneapolis, MN (US); Kellan D. Pauly, Wahpeton, ND (US); Dean E. Sitz, Wahpeton, ND (US); Daniel P. Stubbs, Marine on St. Croix, MN (US)

Correspondence Address: ERIC LEVINSON;IMATION LEGAL AFFAIRS, IMATION CORP., P.O. BOX 64898, ST. PAUL, MN, 55164, US

(21) Appl. No.: 11/413,799

(22) Filed: Apr. 28, 2006

Related U.S. Application Data
(63) Continuation-in-part of application No. 11/144,440, filed on Jun. 3, 2005.

(51) Int. Cl. H01L 43/00; H01L 29/82

(52) U.S. Cl. 257/421

(57) ABSTRACT

The invention is directed to a magnetic field sensing device (FSD) capable of visually indicating exposure to a magnetic field with a strength that exceeds a threshold value. The magnetic FSD comprises a magnetic layer magnetized to define a pattern. The threshold value is approximately equal to a coercivity of the magnetic layer of the FSD, which is at least approximately 3000 Oersteds. The pattern becomes visible when a finely divided magnetic material is applied over the magnetic layer. Then, when the FSD is exposed to a magnetic field with a strength that exceeds the threshold, the pattern visibly alters (e.g., typically disappears altogether). Accordingly, upon re-application of the finely divided magnetic material, the alteration of the pattern is evidence of successful degaussing.

### CROSS-REFERENCE TO RELATED APPLICATIONS

This application is a continuation-in-part of U.S. application Ser. No. 11/144,440 filed Jun. 3, 2005, for Lindblom et al., entitled “Magnetic Field Sensing Device,” and bearing attorney docket number 10501US01; said U.S. application Ser. No. 11/144,440 is incorporated herein by reference in its entirety.

### TECHNICAL FIELD

The invention relates to magnetic media and, more particularly, to erasing, i.e., degaussing, of magnetic media.

### BACKGROUND

As the quantity of data stored in digital form continues to rapidly increase, maintaining secure control of sensitive individual, business, financial institution, and government agency digital data becomes increasingly difficult. Data is often stored, for example, as discrete magnetization patterns on magnetic data storage media, such as magnetic tape or disks. One aspect of digital data security for magnetic media is erasure, i.e., degaussing, of the media. Degaussing is commonly performed to eliminate stored information from magnetic media, and can be very important, particularly when the data to be erased is confidential, private, or highly classified. Degaussing is also commonly performed during media fabrication, e.g., prior to servo writing to ensure that the servo patterns can be properly written.

In general, degaussing of a magnetic medium involves exposing the medium to a magnetic field of sufficient strength, e.g., flux density, to randomly magnetize the medium, thereby destroying the discrete magnetization patterns which comprise the stored data. Degaussing devices may employ a variety of techniques to create such a magnetic field, such as use of alternating or pulsed current to drive a coil. These techniques provide an alternating or pulsed magnetic field, respectively. Other degaussing devices employ a fixed magnet. Fixed magnet degaussing devices are typically used for “emergency” data destruction applications where a means to destroy data without external power is required.

A magnetic field sensing device (FSD) may be applied to a magnetic medium to detect magnetic field strength in order to confirm that the degaussing device generates a field with strength adequate to degauss the magnetic medium. FSDs typically include a magnetic sensor, such as a Hall effect probe, and associated electronics. Such devices may be bulky and expensive. Further, the FSDs may require additional instrumentation for readout of the field strength measurement, which is typically a temporary value displayed via a digital display.

### SUMMARY

In general, the invention is directed to a magnetic field sensing device capable of visually indicating exposure to a magnetic field that exceeds a threshold magnetic field strength value. The magnetic field sensing device (FSD) comprises a magnetic layer magnetized in a pattern, and a material positioned adjacent the magnetic layer to render the pattern visible. The threshold magnetic field strength value is approximately equal to a coercivity of the magnetic layer of the FSD, which is at least approximately 3000 Oersteds (Oe). When the FSD is exposed to a magnetic field that exceeds the threshold, the pattern visibly alters. In some cases, the FSD may include a plurality of patterned magnetic layers, each with different coercivities. In this way, the FSD can indicate an approximate strength of a magnetic field based on which of the patterns of the plurality of magnetic layers visibly alters.

The FSD may comprise a magnetic layer exhibiting a temperature dependent coercivity such that the coercivity of the magnetic layer substantially decreases when the temperature of the magnetic layer increases. Because of this temperature dependent coercivity, the magnetic layer may be heated to enable recording of the desired pattern with applied recording fields which are much lower than the room temperature coercivity of the magnetic layer. Upon cooling to room temperature, the magnetic layer regains coercivity of at least approximately 3000 Oe while maintaining the thermo-magnetically recorded pattern.

In some FSD embodiments, the material adjacent to the magnetic layer is a finely divided magnetic material. In such embodiments, the finely divided magnetic material adjacent the magnetic layer is attracted to areas of the pattern where fringing magnetic fields project from the magnetic layer, e.g., areas where magnetic transitions occur. The pattern may comprise a first region with uniform magnetization and a second region with alternating magnetization, and the finely divided magnetic material may be attracted to the areas with alternating magnetization.

The finely divided magnetic material may comprise a Ferro-fluid, e.g., a colloidal suspension of magnetic particles in fluid, or a dry magnetic powder. In either of these cases, when the FSD is exposed to a magnetic field larger than the threshold value, the magnetization pattern of the magnetic layer alters. When the magnetization pattern of the magnetic layer alters, the originally recognizable pattern made visible by decoration with the finely divided magnetic material is also altered and may become unrecognizable, thereby indicating exposure of the device to a field larger than the threshold value. The FSD may comprise a casing that encloses the finely divided magnetic material between the casing and the magnetic layer.

The FSD may be attached to a data storage device, such as a magnetic tape cartridge or a hard disk drive. An erasure device, i.e., a degausser, may apply a magnetic field to the data storage device to erase data stored on the data storage device. In order to ensure that the data stored by the data storage device is substantially completely erased, the erasure device applies a magnetic field substantially larger than a coercivity of media within the data storage device. In some cases the applied magnetic field may be at least 30% larger than the coercivity of the media within the data storage device. The magnetic layer of the FSD exhibits a coercivity approximately equal to the magnetic field needed to ensure that the data stored by the data storage device is substantially completely erased. In this way, when the data storage device is exposed by the erasure device to the magnetic field, the FSD verifies that the data stored on the data storage device has been substantially completely erased when the pattern visibly alters.

The FSD may have dimensions of approximately 5.0 cm (2.0 inches) long and approximately 1.8 cm (0.7 inches) wide. The small size of the FSD allows the FSD to attach to a side of a data storage device. The FSD may also provide a substantially small profile so as to not interfere with operation of the data storage device, e.g., insertion into a tape drive in the case of a magnetic tape cartridge.

In one embodiment, the invention is directed to a magnetic field sensing device comprising a substrate, a magnetic layer formed over the substrate and magnetized in a pattern, wherein the magnetic layer has a coercivity that is greater than approximately 3000 Oersteds, and a material positioned adjacent the magnetic layer to render the pattern visible. The pattern visibly alters when exposed to a magnetic field with a strength that is greater than the coercivity of the magnetic layer.

In another embodiment, the invention is directed to a system comprising a data storage device that comprises a medium and a magnetic field sensing device. The magnetic field sensing device includes a substrate, a magnetic layer formed over the substrate, wherein the magnetic layer is magnetized in a pattern and has a coercivity of at least approximately 3000 Oersteds, and a material positioned adjacent the magnetic layer to render the pattern visible, wherein the pattern visibly alters when the data storage device is exposed to a magnetic field with a strength greater than the coercivity of the magnetic layer. The coercivity of the magnetic layer of the magnetic field sensing device is at least approximately 30 percent larger than a coercivity of the medium within the data storage device.

In another embodiment, the invention is directed to a method comprising forming a magnetic layer over a substrate, the magnetic layer having a coercivity greater than approximately 3000 Oersteds at room temperature, heating the magnetic layer to lower the coercivity, magnetizing the magnetic layer in a pattern while the magnetic layer is heated, positioning a casing over the magnetic layer, and placing a finely divided magnetic material between the magnetic layer and the casing, the finely divided magnetic material rendering the pattern visible.

The invention may be capable of providing one or more advantages. For example, the pattern on the magnetic layer of the FSD allows a quick and accurate indication of exposure to a magnetic field above a threshold value without requiring additional instrumentation for readout. A FSD may permanently maintain the magnetic field strength indication for logging purposes. A further advantage of the invention is that the FSD may respond to both static and changing magnetic fields.

Besides being attached directly to a data storage device to provide verification that data contained on the device has been erased, a FSD may have a variety of other applications. For example, a FSD could be attached to a data storage device during transport or shipment to verify that the data stored on the data storage device has not been compromised by excessive magnetic field exposure. A FSD may be used to verify the performance of magnetic media degaussers. Additionally, as there is growing concern regarding potential human health hazards associated with magnetic field exposure, a FSD may have potential application for health care workers and patients, utility company workers and the like.

In other embodiments, a magnetic FSD similar to that described above may be realized without a housing to enclose the Ferro-fluid or other finely divided magnetic material. In such cases, a magnetic field sensing device may comprise a substrate, and a magnetic layer formed over the substrate and magnetized to define a pattern. The magnetic layer may have a coercivity that is greater than approximately 3000 Oersteds. The pattern becomes visible upon application of a finely divided magnetic material over the magnetic layer. The finely divided magnetic material may be applied by a separate applicator apparatus, such as a felt-tip pen that includes Ferro-fluid.

In another embodiment, the invention provides a system comprising a data storage device comprising a magnetic medium, and a magnetic FSD attached to the data storage device. In this case, the magnetic FSD includes a substrate, and a magnetic layer formed over the substrate and magnetized to define a pattern, wherein the magnetic layer has a coercivity that is greater than approximately 3000 Oersteds and wherein the pattern is visibly detectable upon application of a finely divided magnetic material over the magnetic layer. If desired, the system could also allow for automated reading (in addition to visible sensor indication) by use of a magnetic head to magnetically detect the pattern.

In another embodiment, the invention provides a magnetic field sensing kit comprising at least one magnetic field sensing device, and an apparatus to facilitate readout of the magnetic field sensing device. The magnetic field sensing device includes a substrate, and a magnetic layer formed over the substrate and magnetized to define a pattern, wherein the magnetic layer has a coercivity that is greater than approximately 3000 Oersteds. The apparatus facilitates application of the finely divided magnetic material over the magnetic layer, wherein the pattern is visibly detectable upon application of the finely divided magnetic material over the magnetic layer.

In another embodiment, the invention provides a method comprising attaching a magnetic field sensing device to a housing of a magnetic medium, the magnetic field sensing device including a substrate, and a magnetic layer formed over the substrate and magnetized to define a pattern, wherein the magnetic layer has a coercivity that is greater than approximately 3000 Oersteds. The method further comprises applying a finely divided magnetic material over the magnetic layer, wherein the pattern is visibly detectable upon application of the finely divided magnetic material over the magnetic layer, degaussing the magnetic medium, and re-applying the finely divided magnetic material over the magnetic layer, wherein the pattern is no longer visibly detectable following the degaussing upon re-application of the finely divided magnetic material over the magnetic layer.

In an added embodiment, a magnetic field sensing device comprises a substrate, a magnetic layer formed over the substrate, and an adhesive formed on a back side of the substrate, wherein the magnetic field sensing device is attachable to magnetic data storage device via the adhesive and the magnetic layer provides detectable indication of degaussing. In this case, the detectable indication provided by the magnetic layer may be visible, as outlined herein, or alternatively purely magnetic and detected by a magnetic head or sensor. The substrate may comprise a polymeric substrate similar to those commonly used for magnetic tape. In this sense, a sensing device according to this added embodiment may be similar to a strip of high coercivity magnetic tape, with an added layer of adhesive on a back side of the substrate. Detection, in this added embodiment, could occur via automated detection of the magnetization of the field sensing device, e.g., whether or not the magnetic layer is magnetized in a pattern, without the need for application of the finely divided magnetic material to visibly expose a pattern. By defining a relatively high coercivity for the magnetization of the field sensing device (as discussed below), automated detection of erasure of the magnetization on the field sensing device could be sufficient proof of erasure of a medium to which the device is adhered.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a conceptual diagram illustrating use of an example magnetic field sensing device (FSD) during erasure, i.e., degaussing, of a data storage device.

FIG. 2 is a conceptual diagram illustrating an example magnetic FSD.

FIG. 3 is a conceptual diagram illustrating an exploded view of a magnetic FSD that includes a casing.

FIG. 4 is a conceptual diagram illustrating a top view of a magnetic FSD with three patterned magnetic layers.

FIG. 5 is a conceptual diagram illustrating a side view of a magnetic FSD with three patterned magnetic layers.

FIG. 6 is a conceptual diagram illustrating a side view of another magnetic FSD with three patterned magnetic layers.

FIG. 7 is a conceptual diagram illustrating an exploded view of a magnetic FSD with three patterned magnetic layers.

FIG. 8 is a flow diagram illustrating a method of manufacturing a magnetic FSD in accordance with an embodiment of the invention.

FIGS. 9A-9C are top views of a magnetic FSD that does not include a housing for Ferro-fluid.

FIG. 10 is a conceptual side view of the magnetic FSD illustrated in FIGS. 9A-9C.

FIG. 11 is a top view of a magnetic FSD that includes a device like that illustrated in FIGS. 9A-9C attached to a label substrate.

FIG. 12 is a conceptual side view of a magnetic FSD kit that includes the magnetic FSD of FIG. 11 and an apparatus to apply finely divided magnetic particles.

FIG. 13 is a flow diagram illustrating a method of using the kit illustrated in FIG. 12.

### DETAILED DESCRIPTION

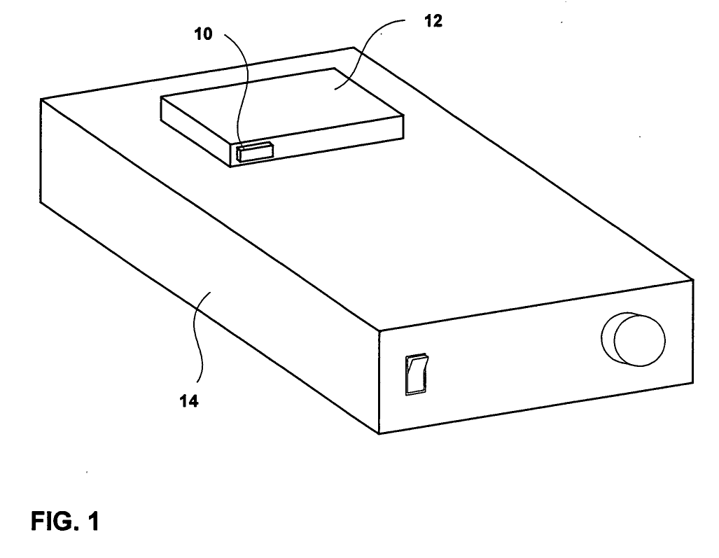

FIG. 1 is a conceptual diagram illustrating use of an example magnetic field sensing device (FSD) 10 during erasure, i.e., degaussing, of a data storage device 12. In the illustrated embodiment, FSD 10 is attached to data storage device 12, which is placed on an erasure device 14, i.e., degaussing device. FSD 10 is capable of visually indicating exposure to a magnetic field that exceeds a threshold value. A user may read FSD 10 to determine whether the strength of the magnetic field generated by erasure device 14, i.e., the strength of the magnetic field that data storage device 12 has been exposed to, exceeds the threshold value. FSD 10 may respond to both static and changing magnetic fields.

In order to substantially completely erase the data stored on data storage device 12, erasure device 14 applies a magnetic field substantially larger than a coercivity of media within data storage device 12. The threshold of FSD 10 may be approximately equal to a magnetic field strength needed to erase data stored on data storage device 12. In this way, when data storage device 12 is exposed by erasure device 14 to a magnetic field, FSD 10 verifies that the data stored on data storage device 12 has been substantially completely erased when the indication visibly alters.

Data storage device 12 may take the form of any magnetic data storage device, such as a magnetic tape cartridge or a hard disk drive. In order to erase data stored on data storage device 12, erasure device 14 exposes substantially the entire volume of data storage device 12 to a magnetic field of sufficient strength to randomly magnetize media within data storage device 12, thereby destroying the discrete magnetization patterns which comprise the data stored on data storage device 12. Erasure device 14 may generate an alternating magnetic field by, for example, energizing one or more electromagnets at the incoming power line frequency (50 or 60 Hz), a pulsed magnetic field by applying pulsed electrical current to one or more electromagnets, or a fixed magnetic field through, for example, inclusion of one or more permanent magnets. FSD 10 according to the invention is not limited to use with any particular type of erasure device 14, data storage device 12, or technique for erasing data stored on data storage device 12.

Media within data storage device 12 may include particulate media or thin film media on which data may be recorded either longitudinally or perpendicularly. As a coercivity of media within data storage device 12 increases, ensuring substantially complete erasure of data stored on data storage device 12 becomes more complicated. In order to substantially completely erase the data stored on data storage device 12, erasure device 14 applies a magnetic field substantially larger than a coercivity of media within data storage device 12. In some cases, the magnetic field produced by erasure device 14 may be at least 30% larger than the coercivity of media within data storage device 12. In other cases, the magnetic field produced by erasure device 14 may be between 30% and 50% larger than the coercivity of media within data storage device 12.

The threshold of FSD 10 may be approximately equal to a magnetic field strength needed to erase data stored on data storage device 12. For example, the threshold may be at least approximately 30% larger, and more preferably between approximately 30% and approximately 50% larger, than the coercivity of the media within data storage device 12. In this way, when data storage device 12 is exposed by erasure device 14 to a magnetic field, FSD 10 verifies that the data stored on data storage device 12 has been substantially completely erased when the indication visibly alters. The large coercivity of the magnetic layer of FSD 10 allows FSD 10 to remain unaltered until exposed to a magnetic field large enough to substantially completely erase data stored on data storage device 12.

FSD 10 comprises a magnetic layer (not shown) magnetized in a pattern and a material adjacent the magnetic layer to render the pattern visible. The threshold value is approximately equal to a coercivity of the magnetic layer of FSD 10, which is greater than approximately 3000 Oersteds (Oe). When FSD 10 is exposed to a magnetic field that exceeds the coercivity, the pattern visibly alters. In some cases the magnetic layer in the FSD is thermo-magnetically patterned by heating the magnetic layer to reduce the coercivity of the magnetic layer. This allows a recording process employing relatively low applied magnetic fields to create the pattern. The coercivity of the magnetic layer then returns to at least approximately 3000 Oe when the magnetic layer cools to room temperature.

In the illustrated example, FSD 10 is attached to data storage device 12. FSD 10 may be attached to data storage device 12, for example, after manufacture or before erasure. The FSD 10 may be used to confirm that data storage device 12 has been exposed to a magnetic field of adequate strength to substantially completely erase data stored on data storage device 12 during erasure by erasure device 14. Attaching FSD 10 to data storage device 12 allows FSD 10 to act as a permanent indicator of substantially complete erasure of data stored on data storage device 12. Each of a number of data storage devices erased by erasure device 14 may be associated with a FSD for this purpose.

In other embodiments, however, FSD 10 may simply be placed on erasure device 14 without data storage device 12, or on an empty cartridge intended to simulate the volume of data storage device 12. In such embodiments, FSD 10 may be used to measure the strength of the magnetic field generated by erasure device 14, e.g., to confirm that the field strength is adequate to substantially completely erase data and/or confirm a field strength indicated by a manufacturer of erasure device 14. Although broadly applicable for use with any type of erasure device 14, data storage device 12, and erasure technique, FSD 10 may be configured for a particular type of erasure device 14, type of data storage device 12, and erasure technique employed by erasure device 14. For example, the threshold of FSD 10 may be selected based on the type of erasure device 14, type of data storage device 12, and erasure technique employed by erasure device 14.

In some embodiments, as illustrated in FIG. 1, FSD 10 is a small card-like or tape-like device that may be affixed to data storage device 12. As will be described in greater detail below, FSD 10 includes a patterned magnetic layer placed on a substrate and a material adjacent the patterned magnetic layer to render the pattern visible. FSD 10 may also comprise a plurality of patterned magnetic layers that exhibit different coercivities, i.e., threshold values. A plurality of magnetic layers, each with a different coercivity, allows FSD 10 to measure an approximate strength of a magnetic field based on which of the patterns of the plurality of magnetic layers visibly alters.

In some embodiments, the material adjacent the patterned magnetic layer may be a finely divided magnetic material that is attracted to portions of the patterned magnetic layer. In such embodiments, FSD 10 may include a casing that encloses the finely divided magnetic material between the casing and the magnetic layer. A bottom of the casing of FSD 10 may have an adhesive layer to allow FSD 10 to be affixed to data storage device 12. The casing may be transparent to protect the patterned magnetic layer. The casing may also be lens-like to allow a user to more easily view the alteration to the pattern caused by exposure of FSD 10 to a magnetic field with a strength that exceeds the threshold value of the magnetic layer. The casing may comprise a form factor small enough to fit on a side of data storage device 12 as illustrated in FIG. 1. A side of data storage device 12 may have a thickness of no more than 2.8 cm (1.1 inches). In that case, the casing may have dimensions of approximately 5.0 cm (2 inches) long and approximately 1.8 cm (0.7 inches) wide.

Although FIG. 1 illustrates only a single FSD 10 affixed to data storage device 12, any number of FSDs 10 may be attached to a single data storage device 12, affixed to a single empty cartridge, or placed together on erasure device 14. A plurality of FSDs 10 may be, for example, arranged as an array to measure the uniformity of the field generated by erasure device 14, or to confirm that the entire volume of a data storage device was exposed to a field of adequate strength for erasure of data stored on the data storage device. In some embodiments, erasure device 14 may generate a multi-axis field, and a plurality of FSDs 10 may be aligned on the respective axes.

Besides providing verification that data contained on data storage device 12 has been substantially completely erased, FSD 10 may have a variety of other applications. For example, FSD 10 could be attached to data storage device 12 during transport or shipment to verify that the data stored on data storage device 12 has not been compromised by excessive magnetic field exposure. Additionally, as there is growing concern regarding potential human health hazards associated with magnetic field exposure, FSD 10 may have potential application for health care workers and patients, utility company workers and the like.

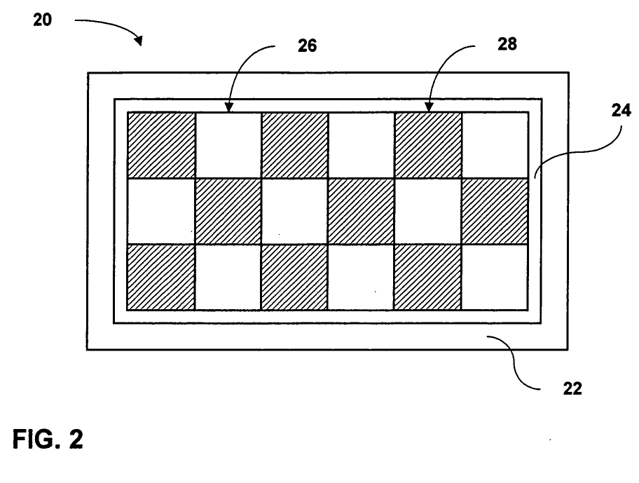

FIG. 2 is a conceptual diagram illustrating an example magnetic FSD 20. FSD 20 is capable of visually indicating exposure to a magnetic field with a strength that exceeds a threshold value. In some embodiments, FSD 20 may be substantially similar to FSD 10 from FIG. 1. For example, FSD 20 may comprise a substantially small form factor and be attached to a data storage device.

FSD 20 comprises a substrate 22 and a magnetic layer 24 placed on substrate 22. Magnetic layer 24 is magnetized in a recognizable pattern. In the illustrated embodiment, a finely divided magnetic material is positioned adjacent magnetic layer 24 to render the pattern visible. Substrate 22 may be formed of a glass, a polymer, or another suitable substrate material. Magnetic layer 24 may be formed of magnetically coated particulate media or thin film media. For example, magnetic layer 24 may comprise conventional magnetic tape or a rare earth transition metal alloy. In addition, magnetic layer 24 may exhibit an easy axis of magnetization either parallel or perpendicular to the plane of magnetic layer 24. Depending on the easy axis direction, magnetic layer 24 may be magnetized in the pattern using either a longitudinal recording process or a perpendicular recording process.

Magnetic layer 24 of FSD 20 exhibits a coercivity greater than approximately 3000 Oe. In some cases, magnetic layer 24 may exhibit a coercivity greater than approximately 5000 Oe or, more preferably, greater than approximately 7000 Oe. In still other cases, magnetic layer 24 may exhibit a coercivity greater than approximately 10000 Oe. The threshold magnetic field value sensed by FSD 20 is approximately equal to the coercivity of magnetic layer 24. When FSD 20 is exposed to a magnetic field that exceeds the coercivity, the pattern visibly alters. FSD 20 may respond to both static and changing magnetic fields.

As described in reference to FIG. 1, FSD 20 may be applied to a data storage device to verify that data stored on the data storage device has been substantially completely erased. However, as a coercivity of media within the data storage device increases, ensuring substantially complete erasure of data stored on the data storage device becomes more complicated. Erasing data stored on a data storage device with high coercivity media may require an erasure device to apply a magnetic field at least 30% larger, more preferably between 30% and 50% larger, than the coercivity of the media within the data storage device.

In order to ensure substantially complete erasure of the data stored on the data storage device, the threshold, i.e., the coercivity, of magnetic layer 24 may be approximately equal to a magnetic field strength needed to erase data stored on the data storage device. For example, the threshold may be at least approximately 30% larger, more preferably between approximately 30% and approximately 50% larger, than the coercivity of the media within the data storage device.

As discussed above, magnetic layer 24 may include particulate media or thin film media with either longitudinal or perpendicular easy axes of magnetization. However, due to the limitations of conventional magnetic recording heads, it becomes difficult to record longitudinal media with a coercivity greater than approximately 5000 Oe. In that case, magnetic layer 24 may comprise, for example, perpendicularly and/or thermo-magnetically recordable particulate or thin film media.

Magnetic layer 24 may exhibit a temperature dependent coercivity such that the coercivity of the magnetic layer substantially decreases when the temperature increases. Consequently, magnetic layer 24 may be heated to allow a recording process employing relatively low applied magnetic fields to magnetize the magnetic layer 24 in the pattern. Upon cooling to room temperature, magnetic layer 24 regains a coercivity of greater than approximately 3000 Oe while maintaining the thermally magnetized pattern.

In the illustrated embodiment, magnetic layer 24 is magnetized in a checkerboard pattern including first regions 26 and second regions 28. First regions 26 have a uniform magnetization in the easy axis direction of magnetic layer 24. Second regions 28 have a magnetization that alternates between parallel and anti-parallel to the easy axis direction of magnetic layer 24. As an example, second regions 28 may comprise approximately 500 flux reversals per millimeter. The boundary between each region of alternating magnetization generates fringing fields in the vicinity of magnetic layer 24. The finely divided magnetic material is preferentially attracted to regions of high fringing fields. Therefore, second regions 28 are populated with the finely divided magnetic material, which renders the checkerboard pattern visible. When FSD 20 is exposed to a magnetic field larger than the coercivity of magnetic layer 24 and in a direction substantially parallel to the easy axis direction of magnetic layer 24, the pattern visibly alters.

In other embodiments, magnetic layer 24 may be magnetized in any type of recognizable pattern that includes a first region with uniform magnetization and a second region with alternating magnetization. The finely divided magnetic material then populates the second region rendering the pattern visible. For example, magnetic layer 24 may be magnetized into a pattern in which the first and second regions form readable text. In that case, exposing FSD 20 to a magnetic field larger than the coercivity of magnetic layer 24 renders the text unreadable.

The finely divided magnetic material may comprise a Ferro-fluid, e.g., a colloidal suspension of magnetic particles in fluid, or a dry magnetic powder. In either of these cases, when FSD 20 is exposed to a magnetic field larger than the threshold value, the magnetic material falls away from second regions 28, rendering the pattern unrecognizable.

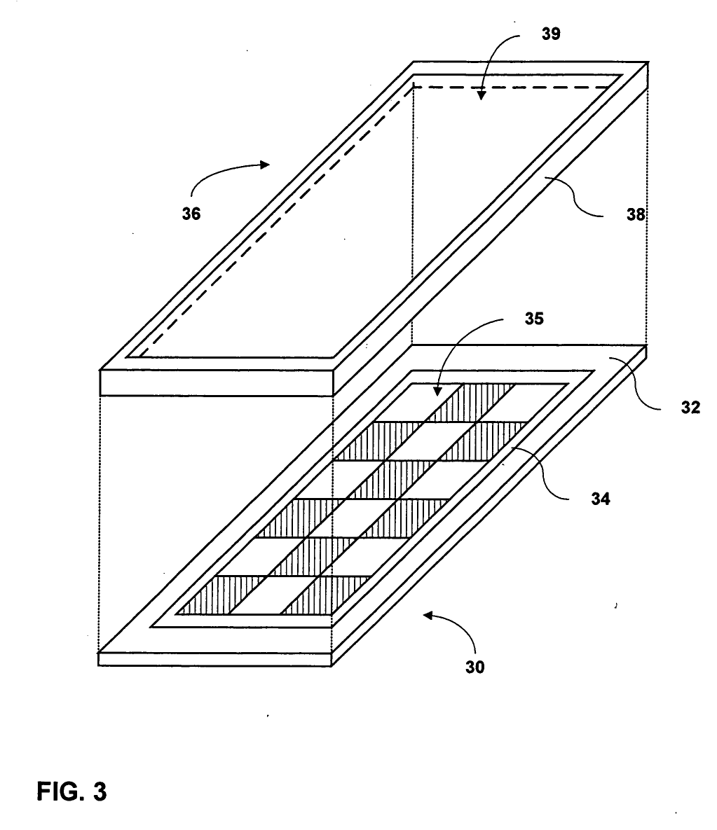

FIG. 3 is a conceptual diagram illustrating an exploded view of a magnetic FSD 30 that includes a casing 36. FSD 30 is capable of visually indicating exposure to a magnetic field that exceeds a threshold value. FSD 30 may be substantially similar to one or both of FSD 10 (FIG. 1) and FSD 20 (FIG. 2). In the illustrated embodiment, casing 36 comprises a cover that attaches to a substrate 32 of FSD 30. In other embodiments, casing 36 may comprise a top portion and a bottom portion that completely encapsulate FSD 30, as described in more detail below.

FSD 30 comprises substrate 32 and a magnetic layer 34 placed on substrate 32. Magnetic layer 34 is magnetized in a recognizable pattern 35 with a finely divided magnetic material positioned adjacent magnetic layer 34 to render pattern 35 visible. Magnetic layer 34 exhibits a coercivity that equals at least approximately 3000 Oe. The coercivity of magnetic layer 34 may be larger than approximately 7000 Oe or larger than approximately 10000 Oe. In some cases, magnetic layer 34 may have a temperature dependent coercivity such that the coercivity substantially decreases when the temperature increases. The threshold value is approximately equal to the coercivity of magnetic layer 34. When FSD 30 is exposed to a magnetic field that exceeds the coercivity, pattern 35 visibly alters.

The finely divided magnetic material may comprise a Ferro-fluid, i.e., a colloidal suspension of magnetic particles in fluid, or a dry magnetic powder. Casing 36 encloses the finely divided magnetic material between casing 36 and magnetic layer 34. When the finely divided magnetic material comprises Ferro-fluid, casing 36 may provide a reservoir to contain the Ferro-fluid adjacent magnetic layer 34. In addition, casing 36 may be hermetically sealed to substantially eliminate the possibility of the Ferro-fluid leaking out of casing 36 or evaporating. For example, casing 36 may allow the use of either laser welding or ultrasonic welding to secure the enclosure.

As shown in FIG. 3, casing 36 includes a frame 38 and a transparent film 39. Frame 38 may comprise a rigid plastic or a thermoformed flexible plastic. Transparent film 39 may comprise an optically clear polycarbonate film. When casing 36 is attached to substrate 32, transparent film 39 allows a user to view pattern 35 on magnetic layer 34 to determine the level of magnetic field exposure. In some embodiments, transparent film 39 comprises a magnifying lens that further improves visibility of pattern 35 on magnetic layer 34.

In some cases, a reflective layer of aluminum, gold, or other materials may be coated over the top of magnetic layer 34 to improve its reflectivity and the visibility of pattern 35. The reflective layer may be particularly useful when magnetic layer 34 is formed of a particulate tape media.

FSD 30 may be attached to a data storage device, e.g., a magnetic tape cartridge or a hard disk drive. In order to fit on a side of the data storage device, casing 36 may comprise a substantially small form factor. As an example, a side of a hard disk drive may have a thickness of no more than 2.8 cm (1.1 inches). In that case, casing 36 may have dimensions of approximately 5.0 cm (2 inches) long and approximately 1.8 cm (0.7 inches) wide. In other embodiments, casing 36 may comprise a form factor sized to fit on a different data storage device.

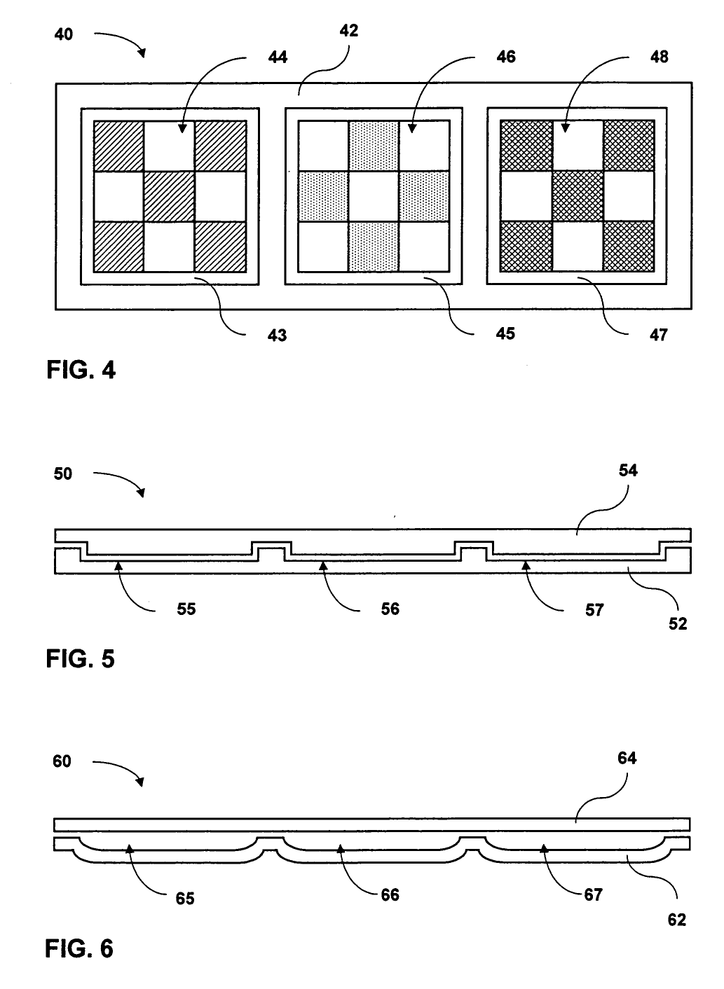

FIG. 4 is a conceptual diagram illustrating a top view of a magnetic FSD 40 with three patterned magnetic layers. FSD 40 is capable of visually indicating exposure to a magnetic field that exceeds any of three threshold values. FSD 40 may respond to both static and changing magnetic fields. In some embodiments, FSD 40 may be substantially similar to FSD 10 from FIG. 1. For example, FSD 40 may comprise a substantially small form factor and be attached to a data storage device.

FSD 40 comprises a substrate 42, a first magnetic layer 43, a second magnetic layer 45, and a third magnetic layer 47 formed over substrate 42. First magnetic layer 43 is magnetized in a first pattern 44, second magnetic layer 45 is magnetized in a second pattern 46, and third magnetic layer 47 is magnetized in a third pattern 48. A finely divided magnetic material is positioned adjacent magnetic layers 43, 45, and 47 to render the respective patterns 44, 46, and 48 visible. Patterns 44, 46 and 48 may be visibly different, or may be substantially similar.

Substrate 42 may be formed of a glass, a polymer, or another suitable substrate material. The finely divided magnetic material may comprise a Ferro-fluid, e.g., a colloidal suspension of magnetic particles in fluid, or a dry magnetic powder. Magnetic layers 43, 45, and 47 may be formed of, for example, magnetically coated particulate media or thin film media. For example, magnetic layers 43, 45, and 47 may comprise conventional magnetic tape or a rare earth transition metal alloy. In some embodiments, each of magnetic layers 43, 45, and 47 may comprise a different material. This may be advantageous when only one or two of the magnetic layers are formed of thin film media and the remaining magnetic layers may be formed of a particulate media, which is much less expensive than the thin film media.

Each of magnetic layers 43, 45, and 47 has a different coercivity, which are at least approximately 3000 Oe. The coercivities of magnetic layers 43, 45, and 47 may be larger than approximately 7000 Oe or larger than approximately 10000 Oe. In some cases, magnetic layers 43, 45, and 47 may exhibit temperature dependent coercivities such that the coercivity substantially decreases when the temperature increases. In this way, magnetic layers 43, 45, and 47 may be heated to allow a recording process employing relatively low applied magnetic fields to magnetize the high coercivity magnetic layers in the respective patterns. The threshold values are approximately equal to the coercivities of magnetic layers 43, 45, and 47. The progression of magnetic layers 43, 45, and 47, each with a different coercivity, allows FSD 40 to measure an approximate strength of a magnetic field based on which of the patterns of the magnetic layers visibly alters.

In the illustrated embodiment, patterns 44, 46, and 48 include first regions that have a uniform magnetization and second regions that have alternating magnetization. The boundary between each region of alternating magnetization generates fringing fields in the vicinity of respective magnetic layers 43, 45, and 47. The finely divided magnetic material is preferentially attracted to regions of high fringing fields. Therefore, the second regions of patterns 44, 46, and 48 are populated with the finely divided magnetic material, which renders the patterns visible. When FSD 40 is exposed to a magnetic field with a strength greater than the coercivity of first magnetic layer 43, first pattern 44 visibly alters. When FSD 40 is exposed to a magnetic field with a strength greater than the coercivity of second magnetic layer 45, second pattern 46 visibly alters. When FSD 40 is exposed to a magnetic field with a strength greater than the coercivity of third magnetic layer 47, third pattern 48 visibly alters.

FSD 40 may be useful when a more exact indication of magnetic field strength is desired. Instead of simply indicating exposure to a magnetic field that exceeds a single threshold value, FSD 40 may indicate exposure to a magnetic field within a range of threshold values. For example, first magnetic layer 43 exhibits a coercivity of approximately 5000 Oe, second magnetic layer 45 exhibits a coercivity of approximately 7500 Oe, and third magnetic layer 47 exhibits a coercivity of approximately 10000 Oe. When FSD 40 is exposed to a magnetic field with a strength of approximately 8000 Oe, both first pattern 44 and second pattern 46 visibly alter, but third pattern 48 is maintained. In this way, a user may visually determine that the magnetic field exhibited a strength between approximately 7500 Oe and 10000 Oe.

FIG. 5 is a conceptual diagram illustrating a side view of a magnetic FSD 50 with three patterned magnetic layers. FSD 50 is substantially similar to FSD 40 from FIG. 4. In the illustrated embodiment, FSD 50 comprises three magnetic layers, each layer exhibiting a respective coercivity. FSD 50 also comprises a casing with a top portion 54 and a bottom portion 52. Bottom portion 52 of the casing defines wells 55, 56, and 57 for each of the three magnetic layers. In other embodiments, FSD 50 may comprise any number of magnetic layers and bottom portion 52 of the casing may define any number of wells.

Top portion 54 and bottom portion 52 of the casing substantially completely encapsulate FSD 50. Bottom portion 52 may include a substrate and patterned magnetic layers placed in each of wells 55, 56, and 57. A finely divided magnetic material is positioned adjacent the three magnetic layers to render the respective patterns visible. Top portion 54 then encloses the finely divided magnetic material between the magnetic layers and top portion 54.

The finely divided magnetic material may comprise a Ferro-fluid, e.g., a colloidal suspension of magnetic particles in fluid, or a dry magnetic powder. When the finely divided magnetic material comprises Ferro-fluid, wells 55, 56, and 57 in bottom portion 52 of the casing contain the Ferro-fluid adjacent the magnetic layers. In addition, as shown in FIG. 5, the casing includes channels between wells 55, 56, and 57 through which the Ferro-fluid can pass. Top portion 54 and bottom portion 52 may be hermetically sealed together to substantially eliminate the possibility of the Ferro-fluid leaking out of the casing or evaporating. For example, the casing may allow the use of either laser welding or ultrasonic welding to secure the enclosure. Alternatively, an adhesive such as a cyanoacrylate material, a photocurable acrylate material, a silicone material or the like may be used to hermetically seal the casing.

In the illustrated embodiments, top portion 54 and bottom portion 52 comprise a rigid plastic. Top portion 54 may include an optically clear polycarbonate material to allow a user to view the patterns on the magnetic layers to determine the level of magnetic field exposure. In some embodiments, top portion 54 comprises a magnifying lens that further improves visibility of the patterns on the magnetic layers. In other embodiments, a separate external viewer may be applied to the optically clear material of top portion 54.

FSD 50 may be attached to a data storage device, e.g., a magnetic tape cartridge or a hard disk drive. In order to fit on a side of the data storage device, the casing may comprise a substantially small form factor. As an example, the casing may have dimensions of approximately 5.0 cm (2 inches) long and approximately 1.8 cm (0.7 inches) wide. In other embodiments, FSD 50 may not be attached to a data storage device and the casing may comprise a different form factor.

FIG. 6 is a conceptual diagram illustrating a side view of another magnetic FSD 60 with three patterned magnetic layers. FSD 60 is substantially similar to FSD 40 from FIG. 4. In the illustrated embodiment, FSD 60 comprises three magnetic layers with different coercivities. FSD 60 also comprises a casing with a top portion 64 and a bottom portion 62. Bottom portion 62 of the casing defines wells 65, 66, and 67 for each of the three magnetic layers. In other embodiments, FSD 60 may comprise any number of magnetic layers and bottom portion 62 of the casing may define any number of wells.

Top portion 64 and bottom portion 62 of the casing substantially completely encapsulate FSD 60. Bottom portion 62 may include a substrate and patterned magnetic layers placed in each of wells 65, 66, and 67. A finely divided magnetic material is positioned adjacent the three magnetic layers to render the respective patterns visible. Top portion 64 then encloses the finely divided magnetic material between the magnetic layers and top portion 64.

The finely divided magnetic material may comprise a Ferro-fluid, e.g., a colloidal suspension of magnetic particles in fluid, or a dry magnetic powder. When the finely divided magnetic material comprises Ferro-fluid, wells 65, 66, and 67 in bottom portion 62 of the casing contain the Ferro-fluid adjacent the magnetic layers. In addition, as shown in FIG. 6, the casing includes channels between wells 65, 66, and 67 through which the Ferro-fluid can pass. Top portion 64 and bottom portion 62 may be hermetically sealed together to substantially eliminate the possibility of the Ferro-fluid leaking out of the casing or evaporating. For example, the casing may allow the use of either laser welding or ultrasonic welding to secure the enclosure.

In the illustrated embodiments, top portion 64 and bottom portion 62 comprise a thermoformed flexible plastic. Top portion 64 may include an optically clear film to allow a user to view the patterns on the magnetic layers to determine the level of magnetic field exposure. In some embodiments, top portion 64 comprises a magnifying lens that further improves visibility of the patterns on the magnetic layers. In other embodiments, a separate external viewer may be applied to the optically clear film of top portion 64.

FSD 60 may be attached to a data storage device, e.g., a magnetic tape cartridge or a hard disk drive. In order to fit on a side of the data storage device, the casing may comprise a substantially small form factor. As an example, the casing may have dimensions of approximately 5.0 cm (2 inches) long and approximately 1.8 cm (0.7 inches) wide. In other embodiments, FSD 60 may not be attached to a data storage device and the casing may comprise a different form factor.

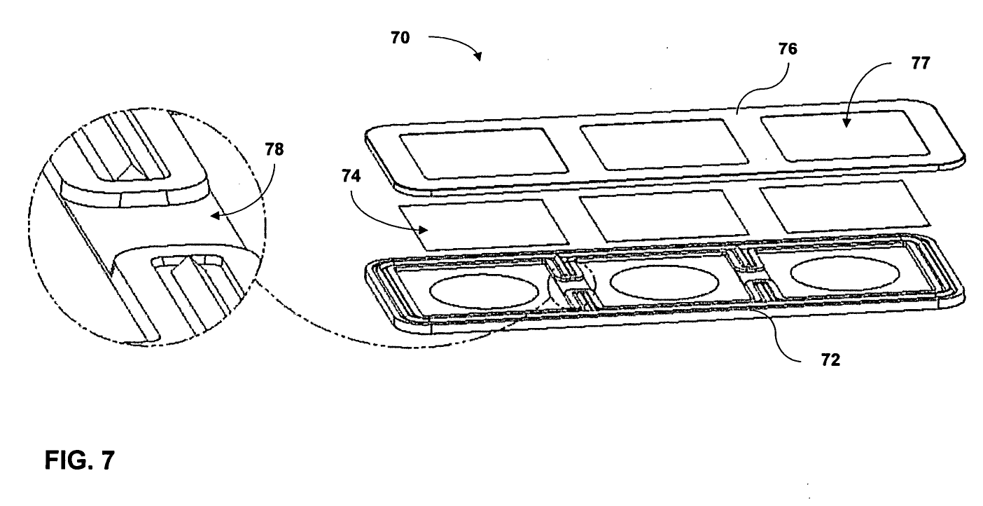

FIG. 7 is a conceptual diagram illustrating an exploded view of a magnetic FSD 70 with three patterned magnetic layers. FSD 70 may be substantially similar to FSD 50 from FIG. 5 or FSD 60 from FIG. 6. In the illustrated embodiment, FSD 70 comprises three magnetic layers 74 with different coercivities. Magnetic layers 74 are capable of visually indicating exposure to a magnetic field that exceeds any of three threshold values that corresponded to the different coercivities of magnetic layers 74.

FSD 70 comprises a casing with a top portion 76 and a bottom portion 72. Bottom portion 72 of the casing defines regions for each of the three magnetic layers 74. In other embodiments, FSD 70 may comprise any number of magnetic layers and bottom portion 72 of the casing may define any number of regions. Each of magnetic layers 74 is magnetized in a recognizable pattern. A finely divided magnetic material is positioned adjacent magnetic layers 74 to render the respective patterns visible. Top portion 76 then encloses the finely divided magnetic material between magnetic layers 74 and top portion 76.

Each of magnetic layers 74 exhibits a different coercivity, which is at least 3000 Oe. In some cases, magnetic layers 74 may exhibit temperature dependent coercivities such that the coercivity substantially decreases when the temperature increases. The progression of magnetic layers 74, each with a different coercivity, allows FSD 70 to measure an approximate strength of a magnetic field based on which of the patterns of the magnetic layers visibly alters.

The finely divided magnetic material may comprise a Ferro-fluid, e.g., a colloidal suspension of magnetic particles in fluid, or a dry magnetic powder. When the finely divided magnetic material comprises Ferro-fluid, top portion 76 and bottom portion 72 may be hermetically sealed together to substantially eliminate the possibility of the Ferro-fluid leaking out of the casing or evaporating. In addition, as shown in the detail of FIG. 7, the casing includes channels 78 in bottom portion 72 between the regions through which the Ferro-fluid can pass. In this way, the Ferro-fluid may be injected into one of the regions defined in bottom portion 72 even after top portion 76 and bottom portion 72 are sealed together. The Ferro-fluid will pass through channels 78 to fill the other defined regions in bottom portion 72.

Top portion 76 and bottom portion 72 may comprise either a rigid plastic or a thermoformed flexible plastic. Top portion 76 includes a transparent material 77 over each of magnetic layers 74. Transparent material 77 allows a user to view the patterns on magnetic layers 74 to determine the level of magnetic field exposure. In some embodiments, transparent material 77 comprises a magnifying lens that further improves visibility of the patterns on magnetic layers 74. In other embodiments, a separate external viewer may be applied to top portion 76 over transparent material 77.

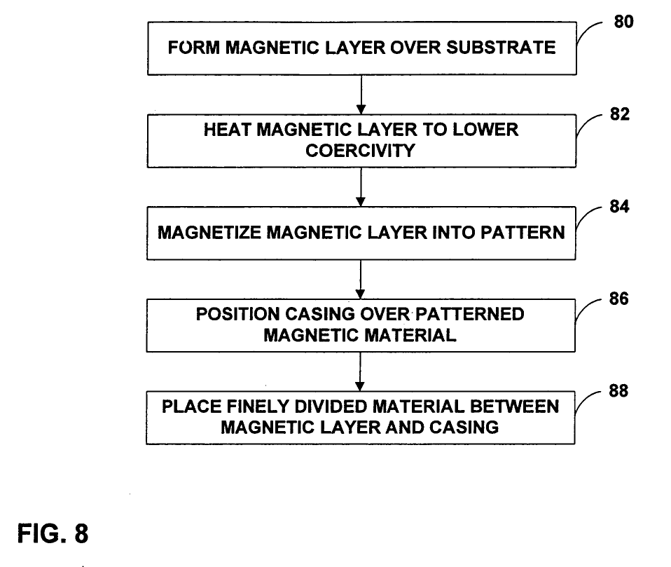

FIG. 8 is a flow chart illustrating a method of manufacturing a FSD in accordance with an embodiment of the invention. The method is described in reference to FSD 30 of FIG. 3. Substrate 32 may be formed of a glass, a polymer, or another suitable substrate material. Magnetic layer 34, which may be formed of magnetically coated particulate media or thin film media, is formed over substrate 32 (80). Magnetic layer 34 has a coercivity greater than approximately 3000 Oe at room temperature, more preferably greater than approximately 5000 Oe at room temperature, and even more preferably greater than approximately 7000 Oe at room temperature.

As described above, magnetic layer 34 may exhibit a temperature dependent coercivity such that the coercivity substantially decreases when the temperature increases. Magnetic layer 34 is heated to lower the coercivity of magnetic layer 34 (82). Magnetic layer 34 may then be magnetized in pattern 35 (84). Magnetic layer 34 may be magnetized in any type of recognizable pattern that includes a first region with uniform magnetization and a second region with alternating magnetization. Heating magnetic layer 34 allows a recording process employing relatively low applied magnetic fields to be used to record pattern 35 on magnetic layer 34, which returns to a high coercivity upon cooling to room temperature.

Casing 36 is then positioned over magnetic layer 34 (86). Casing 36 includes a frame 38, which is affixed to substrate 32, and a transparent film 39, which may comprise a magnifying lens to improve visibility of pattern 35. The finely divided magnetic material is placed between magnetic layer 34 and casing 36 (88). For example, in the case where the finely divided magnetic material comprises a Ferro-fluid, the Ferro-fluid may be injected through casing 36 using a syringe. The finely divided magnetic material is attracted to areas of pattern 35 with the highest magnetic fields. Therefore, the finely divided magnetic material populates the second region of pattern 35 which renders pattern 35 visible.

As described above, the material adjacent to the magnetic layer that renders the pattern visible may be a finely-divided magnetic material, such as a Ferro-fluid, or a dry magnetic powder.

In other embodiments, the magnetic FSD similar to that described above may be realized without a housing to enclose the Ferro-fluid or other finely divided magnetic material. Instead, referring again to FIG. 2, FSD 20 may be realized solely with substrate 22 and one or more magnetic layers 24. In this case, a separate apparatus may be used to apply the finely divided magnetic material to the surface of magnetic layer 24 to facilitate readout. In other words, finely divided magnetic material can be placed adjacent magnetic layer 24 via an application process. In this case, the need for a housing or casing is eliminated, and the FSD is simplified.

In this example, the apparatus used to apply the finely divided magnetic material may comprise a felt-tip pen that includes a Ferro-fluid or other colloidal suspension of magnetic particles. According to this embodiment, FSD 20 may include an adhesive on the back side of substrate 22, and may be adhered to a cartridge of a magnetic data storage medium. Following a degaussing process, a user can manually apply the finely divided magnetic material to the surface of FSD 20, which causes the pattern to appear only if the degaussing process was insufficient to erase the magnetically recorded pattern. This embodiment can reduce the cost of FSD 20 insofar as the need for a casing or housing is eliminated. Moreover, the potential for leakage of Ferro-fluid may also be reduced or eliminated.

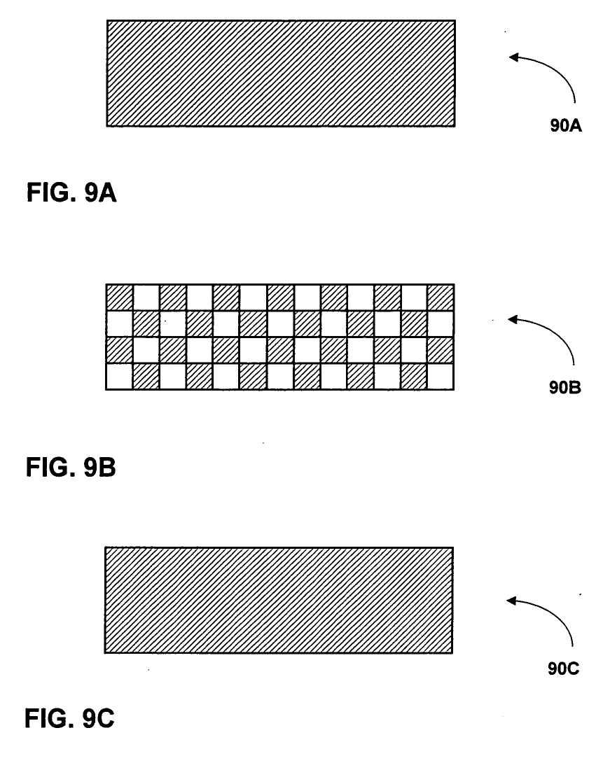

FIGS. 9A-9C are top views of a magnetic FSD that does not include a housing for Ferro-fluid. FIG. 9A conceptually illustrates the magnetic FSD 90A prior to application of finely divided magnetic particles, FIG. 9B conceptually illustrates the magnetic FSD 90B after application of the finely divided magnetic particles, and FIG. 9C conceptually illustrates the magnetic FSD 90C after re-application of the finely divided magnetic particles following a degauss. Generally, FSD 90 refers to any of FSD 90A, 90B or 90C illustrated in FIGS. 9A-9C respectively.

FSD 90 may include any of the features described above, but lacks a housing or casing to hold Ferro-fluid. Instead, a user applies the Ferro-fluid (or other finely divided magnetic material) to the surface of FSD 90 at the time when the user wants to read the sensor. Originally, FSD 90 may appear substantially reflective. The magnetic surface of FSD 90, however, is recorded with a magnetic pattern, which, following application of a finely divided magnetic material, becomes visible. The visibility of the pattern may be conspicuous such that a user with regular “20-20” vision can easily detect the pattern without the aid of magnification.

The user may apply finely the divided magnetic material over FSD 90 in any manner. In one example, an application apparatus is provided with FSD 90 as part of a field sensing kit. The application apparatus, for example, may comprise a felt-tip pen that includes Ferro-fluid, or another device that allows application of magnetic particles in a fluid or powder. In any case, following application of the finely divided magnetic material over the surface of FSD 90, the pattern becomes visible as shown in FSD 90B of FIG. 9B. Then, after FSD 90 has been exposed to a degaussing process, another application of finely divided magnetic material is applied over the surface of FSD 90. At this point, the pattern is no longer visible as shown in FSD 90C of FIG. 9C.

In practice, a user may affix FSD 90 to a cartridge or housing of a magnetic data storage medium. The user may then apply the finely divided magnetic material to expose the pattern (as shown in FIG. 9B) just prior to the degaussing process in order to verify that FSD 90 has not been previously erased. The cartridge is then degaussed, and following the degaussing process, finely divided magnetic material is re-applied to the surface of FSD 90. At this point, if the pattern is no longer visible, then the degaussing process was successful.

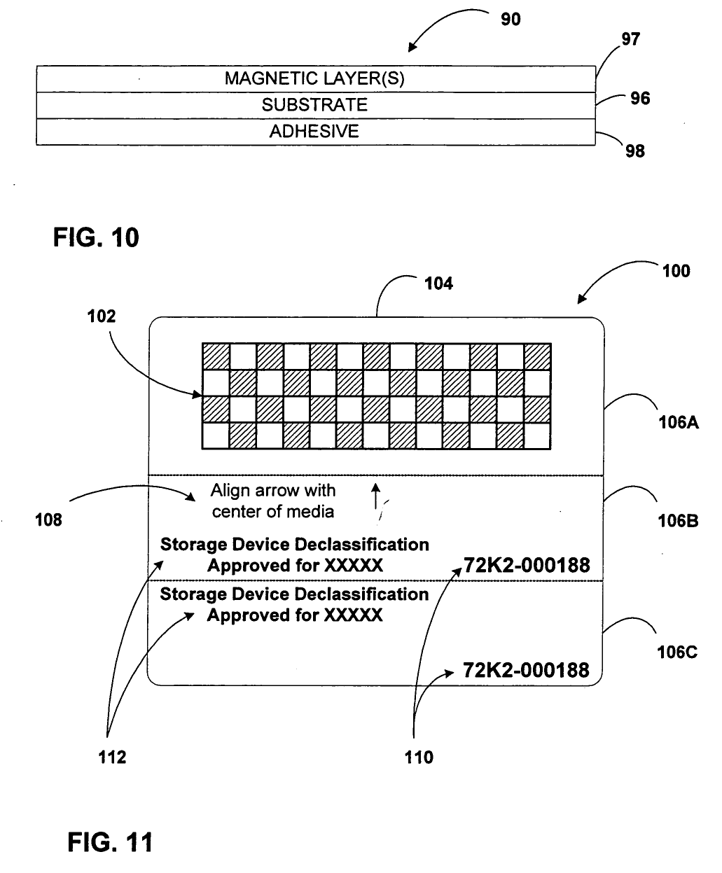

FIG. 10 is a conceptual side view of the magnetic FSD 90 illustrated in FIGS. 9A-9C. As shown in FIG. 10, magnetic FSD 90 includes a substrate 96 and one or more magnetic layers 97 formed over substrate 96. An adhesive is formed on the back side of substrate 96 to allow for easy attachment of FSD 90 to a tape cartridge, a hard drive or other magnetic data storage medium to be degaussed. Substrate 96 may comprise a polymeric material, such as those commonly used for the formation of magnetic tape. The one or more magnetic layers 97 generally conform to any of the magnetic layers described herein. Importantly, the one or more magnetic layers 97 define a pattern that becomes visible upon application of a finely divided magnetic material over the magnetic layer(s) 97.

For example, the coercivity of magnetic layer(s) 97 may be greater than approximately 3000 Oe, greater than approximately 5000 Oe, greater than approximately 7000 Oe, or possibly greater than approximately 10,000 Oe. Coercivity in the rage of approximately 7000-10,000 Oe is acceptable for use with most magnetic media. Generally the coercivity of magnetic layer(s) 97 should be substantially greater than the coercivity of the magnetic layers in the medium that is being degaussed, and is typically approximately 30-50 percent greater than the coercivity of the magnetic medium. The coercivity of the magnetic layer(s) 97 may substantially decrease when a temperature of the magnetic layer increases, and the magnetic layer(s) are magnetized in the pattern at an elevated temperature.

The one or more magnetic layers 97 may comprise a rare earth transition metal alloy, and may be perpendicularly recorded. Alternatively, a multi-layer thin film structure, e.g., with alternating layers of platinum and cobalt or alternatively layers of palladium and cobalt may be used. Also, many other magnetic layer structures could be used, as long as the magnetic layer(s) 97 defines the pattern as described herein.

The pattern formed on magnetic layer(s) 97 is generally any pattern that becomes conspicuously visible upon application of the finely divided magnetic material. For example, the pattern may be checkerboard pattern that becomes visible upon application of the finely divided magnetic material over the magnetic layer. Alternatively, the pattern may define one or more letters or symbols that become visible upon application of the finely divided magnetic material over the magnetic layer, e.g., to convey a message to the user.

For a checkerboard pattern (as outlined above), the pattern may comprise a first region with uniform magnetization and a second region with alternating magnetization, wherein upon application of the finely divided magnetic material, the finely divided magnetic material populates the second region rendering the pattern visible. Many other configurations of magnetic layer(s) 97 could be used to realize the ability to record a pattern that becomes conspicuously visible upon application of the finely divided magnetic material.

FIG. 11 is a top view of a magnetic FSD that includes the device like that illustrated in FIGS. 9A-9C attached to a label substrate. In this case, magnetic FSD 100 includes structure 102, which generally conforms to FSD 90 of FIGS. 9A-9C and 10. Thus, structure 102 includes a first substrate. This first substrate is then adhered to a second substrate 104, which includes labels, instructions, and/or other information pertinent to degaussing logs. Substrate 104, for example, may comprise a polymeric, paper or cardboard label that includes an adhesive backing to facilitate attachment of FSD 100 to magnetic data storage device. FSD 100 may include several sections 106A, 106B and 106C that are attached, yet perforated, to allow for easy detachment from one another. The first section 106A includes structure 102, which again, generally conforms to FSD 90 of FIGS. 9A-9C and 10. The second section 106B may include instructions 108 for the attachment of FSD 100, as well as log information 112 and a unique identifier 110, the latter of which may be realized as one or more numbers, bar codes, radio frequency identification (RFID) tags, or any other indicia to facilitate recordkeeping or tracking. The log information 112 and a unique identifier 110 may also be included in third section 106C, which may be removed when FSD 100 is attached to a device. Third section 106C, for example, may be adhered into a record log associated with recordkeeping of the degaussing process performed on magnetic media. Perforations may allow each of sections 106A, 106B and 106C to be easily detached from each other.

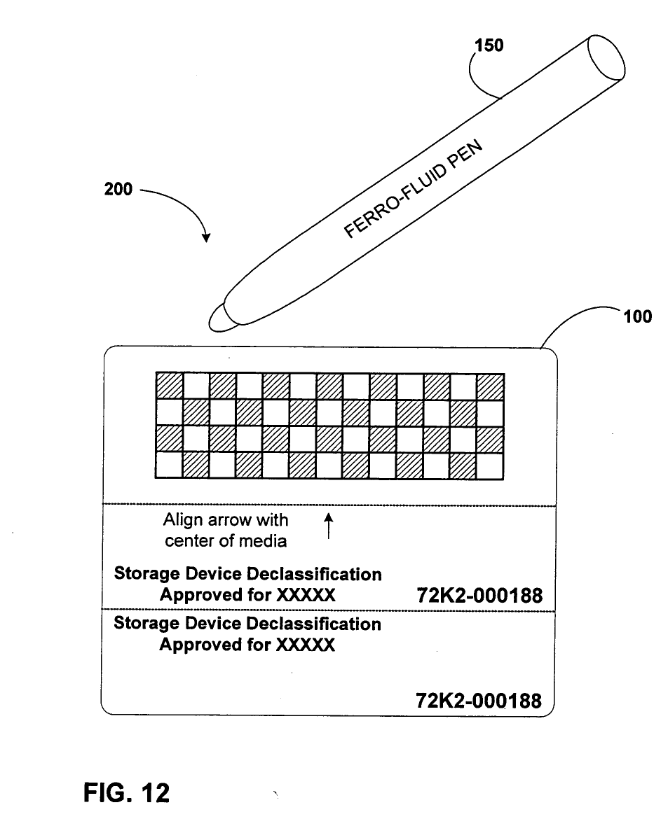

FIG. 12 is a conceptual side view of a magnetic FSD kit 200 that includes the magnetic FSD 100 of FIG. 11 and an apparatus 150 to apply finely divided magnetic particles. In this example, apparatus 150 comprises a felt tip Ferro-fluid pen that includes a colloidal suspension of magnetic particles in a liquid. The checkerboard pattern shown on the surface of FSD 100 may become visible upon application of the finely divided magnetic particles of apparatus 150 over the surface of FSD 100. A user can verify whether FSD 100 has been degaussed by moving the writing tip of apparatus 150 over the surface of FSD 100 to expose the checkerboard pattern. Following a degaussing process, finely divided magnetic particles may be re-applied via apparatus 150 to determine whether the checkerboard pattern has been erased, which would indicate a successful degauss. Other types of applicator apparatuses could be used, such as a brush to apply finely divided magnetic particles in liquid or powder form.

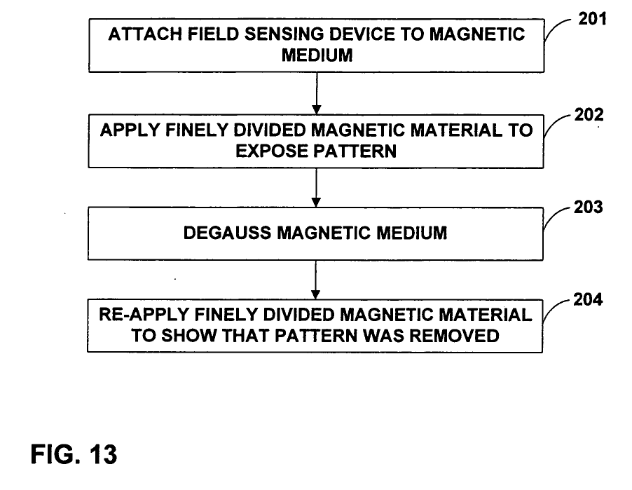

FIG. 13 is a flow diagram illustrating a method of using the kit 200 illustrated in FIG. 12. As shown in FIG. 13, a user attaches a field sensing device 100 to a magnetic medium (201), such as a tape cartridge, a hard drive, or any medium to be erased. The user then applies a finely divided magnetic material to field sensing device 100 to visibly expose the magnetically recorded pattern (202). For example, the user may utilize an apparatus 150 to introduce a Ferro-fluid to the surface of field sensing device 100 to visibly expose the pattern.

Next, the user degausses the magnetic medium (203) in an attempt to fully erase any data from the medium. The user then re-applies divided magnetic material to show that the pattern was removed (204). In this manner, if the degaussing process removes the visible pattern from field sensing device 100, the user can be assured that the degaussing process was successful in removing stored data from the medium. By exposing the pattern just prior to the degaussing process, the integrity of field sensing device 100 is established at the time of use. At any point, the user may also log the fact that the degaussing process was performed and verified with field sensing device 100, e.g., by removing section 106C from device 100 and adhering section 106C into a record log associated with the degaussing of magnetic media.

Various embodiments of the invention have been described. For example, a magnetic field sensing device has been described that includes at least one magnetic layer placed on a substrate and magnetized in a pattern. A finely divided magnetic material may be applied or positioned adjacent the magnetic layer to render the pattern visible. The magnetic layer exhibits a coercivity of at least approximately 3000 Oe. In some cases, the magnetic layer exhibits a temperature dependent coercivity such that the coercivity is at least approximately 3000 Oe at room temperature, and decreases as the temperature of the magnetic layer increases. When the magnetic FSD is exposed to a magnetic field larger than the coercivity of the magnetic layer, the pattern visibly alters. In addition to visible alteration and inspection of the FSD, the invention also contemplates non-visual automated detection of the pattern. In this case, a magnetic head could be used to detect the presence or absence of the pattern, with or without the application of the finely divided magnetic material that renders the pattern visible. These and other embodiments are within the scope of the following claims.

1. A magnetic field sensing device comprising:
a substrate;
a magnetic layer formed over the substrate and magnetized to define a pattern, wherein the magnetic layer has a coercivity that is greater than approximately 3000 Oersteds, and wherein the pattern becomes visible upon application of a finely divided magnetic material over the magnetic layer.

2. The magnetic field sensing device of claim 1, further comprising an adhesive on a back side of the substrate.

3. The magnetic field sensing device of claim 1, wherein the substrate is a first substrate, wherein the first substrate is adhered to a second substrate and wherein the second substrate includes a label on a front side and adhesive on a back side.

4. The magnetic field sensing device of claim 3, wherein the label includes a unique identifier.

5. The magnetic field sensing device of claim 1, wherein the pattern is a checkerboard pattern that becomes visible upon application of the finely divided magnetic material over the magnetic layer.

6. The magnetic field sensing device of claim 1, wherein the pattern defines one or more letters or symbols that become visible upon application of the finely divided magnetic material over the magnetic layer.

7. The magnetic field sensing device of claim 1, wherein the coercivity of the magnetic layer substantially decreases when a temperature of the magnetic layer increases, and the magnetic layer is magnetized in the pattern at an elevated temperature.

8. The magnetic field sensing device of claim 1, wherein the magnetic layer comprises a rare earth transition metal alloy.

9. The magnetic field sensing device of claim 1, wherein the magnetic layer is perpendicularly recorded.

10. The magnetic field sensing device of claim 1, wherein the magnetic layer has a coercivity greater than approximately 5000 Oersteds.

11. The magnetic field sensing device of claim 1, wherein the magnetic layer has a coercivity greater than approximately 7000 Oersteds.

12. The magnetic field sensing device of claim 1, wherein the finely divided magnetic material comprises one of a colloidal suspension of magnetic particles in a liquid, or a dry magnetic powder.

13. The magnetic field sensing device of claim 7, wherein the pattern comprises a first region with uniform magnetization and a second region with alternating magnetization, wherein upon application of the finely divided magnetic material, the finely divided magnetic material populates the second region rendering the pattern visible.

14. A system comprising:
a data storage device comprising a magnetic medium; and
a magnetic field sensing device attached to the data storage device including:
a substrate; and
a magnetic layer formed over the substrate and magnetized to define a pattern, wherein the magnetic layer has a coercivity that is greater than approximately 3000 Oersteds and wherein the pattern is visibly detectable upon application of a finely divided magnetic material over the magnetic layer.

15. The system of claim 14, wherein upon degaussing the system the pattern is no longer visibly detectable upon re-application of the finely divided magnetic material over the magnetic layer.

16. The system of claim 14, wherein the coercivity of the magnetic layer of the magnetic field sensing device is between approximately 30 percent and approximately 50 percent larger than the coercivity of media within the data storage device.

17. The system of claim 14, further comprising a magnetic head to magnetically detect the pattern.

18. A magnetic field sensing kit comprising:
at least one magnetic field sensing device including a substrate, and a magnetic layer formed over the substrate and magnetized to define a pattern, wherein the magnetic layer has a coercivity that is greater than approximately 3000 Oersteds; and
an apparatus to apply a finely divided magnetic material over the magnetic layer, wherein the pattern is visibly detectable upon application of the finely divided magnetic material over the magnetic layer.

19. The magnetic field sensing kit of claim 18, wherein the finely divided magnetic material comprises a colloidal suspension of magnetic particles in a liquid, and wherein the apparatus to apply the finely divided magnetic material comprises a felt tip pen that includes the colloidal suspension of magnetic particles in the liquid.

20. A method comprising:
attaching a magnetic field sensing device to a housing of a magnetic medium, the magnetic field sensing device including a substrate, and a magnetic layer formed over the substrate and magnetized to define a pattern, wherein the magnetic layer has a coercivity that is greater than approximately 3000 Oersteds;
applying a finely divided magnetic material over the magnetic layer, wherein the pattern is visibly detectable upon application of the finely divided magnetic material over the magnetic layer;
degaussing the magnetic medium; and
re-applying the finely divided magnetic material over the magnetic layer, wherein the pattern is no longer visibly detectable following the degaussing upon re-application of the finely divided magnetic material over the magnetic layer.

21. A magnetic field sensing device comprising:
a substrate;
a magnetic layer formed over the substrate; and
an adhesive formed on a back side of the substrate, wherein the magnetic field sensing device is attachable to magnetic data storage device via the adhesive and the magnetic layer provides a detectable indication of degaussing.
